(19) United States
(12) Patent Application Publication
(10) Pub. No.: US 2017/0077369 A1
(43) Pub. Date: Mar. 16, 2017

(54) LIGHT-EMITTING APPARATUS, ILLUMINATION APPARATUS, AND METHOD OF MANUFACTURING LIGHT-EMITTING APPARATUS

(71) Applicant: Panasonic Intellectual Property Management Co., Ltd., Osaka (JP)

(72) Inventor: Katsuyuki NAGAHAMA, Hyogo (JP)

(21) Appl. No.: 15/258,567

(22) Filed: Sep. 7, 2016

(30) Foreign Application Priority Data
Sep. 10, 2015 (JP) 2015-178960

(51) Int. Cl. H01L 33/62; H01L 33/52; H01L 27/15

(52) U.S. Cl. CPC H01L 33/62; H01L 27/153; H01L 33/52; H01L 2933/0066; H01L 2933/005

(57) ABSTRACT

A light-emitting apparatus includes: a substrate; targets to be connected (LED chips and wiring), mounted on the substrate and arranged linearly; wires that individually connect adjacent ones of the targets to each other; and a sealing member provided on the substrate and sealing the targets and the wires. At least one of the wires in a region of the sealing member corresponding to one of ends of a line of the targets is a first wire, at least one of the wires in a region of the sealing member corresponding to the other of the ends is a second wire, and each of the first and second wires has a standing portion attached to one of the targets that is the inner one in the sealing member, and an inclined portion attached to the other of the targets that is the outer one in the sealing member.

### CROSS REFERENCE TO RELATED APPLICATION

This application claims the benefit of priority of Japanese Patent Application Number 2015-178960 filed on Sep. 10, 2015, the entire content of which is hereby incorporated by reference.

### BACKGROUND

1. Technical Field

The present disclosure relates to a light-emitting apparatus in which a light-emitting element is mounted on a substrate, an illumination apparatus including the light-emitting apparatus, and a method of manufacturing the light-emitting apparatus.

2. Description of the Related Art

In a known illumination apparatus, a light-emitting apparatus (a light-emitting module) that uses a semiconductor light-emitting element, such as an LED (light-emitting diode), as a light source is mounted. Specifically, a light-emitting apparatus in which a plurality of LEDs mounted on a substrate are surrounded by a light-reflecting resin (hereinafter referred to also as a dam member) is known (for example, see Japanese Unexamined Patent Application Publication No. 2011-146640). In a region surrounded by the dam member, a plurality of LEDs are provided which are electrically connected by a wire, for example, and a sealing member fills the region so as to seal the plurality of LEDs.

### SUMMARY

The sealing member expands and contracts according to a heat change that occurs upon turning on the apparatus to emit light and upon turning off the apparatus to stop emitting light. This may result in disconnection of the wire.

Thus, an object of the present disclosure is to provide a light-emitting apparatus and an illumination apparatus that are capable of reducing the occurrence of disconnection, and a method of manufacturing the light-emitting apparatus.

A light-emitting apparatus according to an aspect of the present disclosure includes: a substrate; a plurality of targets to be connected, mounted on the substrate and arranged linearly; a plurality of wires that connect the plurality of targets in series by individually connecting adjacent ones of the plurality of targets to each other; and a sealing member provided on the substrate and sealing the plurality of targets and the plurality of wires, wherein the plurality of wires includes a first wire and a second wire, the first wire is included in a region of the sealing member corresponding to one of ends of a line of the plurality of targets, that the second wire is included in a region of the sealing member corresponding to the other of the ends, each of the first wire and the second wire has a standing portion attached to one of targets, and an inclined portion attached to an other of the targets, and the one of the targets is located at an inner position in the sealing member than the other of the targets in a plan view.

An illumination apparatus according to another aspect of the present disclosure includes the above-described light-emitting apparatus.

A method of manufacturing a light-emitting apparatus according to another aspect of the present disclosure is a method of manufacturing the above-described light-emitting apparatus includes when connecting the plurality of targets to each other by forming the plurality of wires by wire bonding: forming the standing portion of each of the first wire and the second wire by first bonding in the wire bonding; and forming the inclined portion of each of the first wire and the second wire by second bonding in the wire bonding.

According to the present disclosure, it is possible to reduce the occurrence of disconnection and thus increase the reliability.

### BRIEF DESCRIPTION OF DRAWINGS

The figures depict one or more implementations in accordance with the present teaching, by way of examples only, not by way of limitations. In the figures, like reference numerals refer to the same or similar elements.

FIG. 1 is a perspective view of an external appearance of a light-emitting apparatus according to Embodiment 1;

FIG. 2 is a plan view of a light-emitting apparatus according to Embodiment 1;

FIG. 3 is a plan view illustrating the internal structure of a light-emitting apparatus according to Embodiment 1;

FIG. 4 is a schematic cross-sectional view of a light-emitting apparatus, taken along line IV-IV in FIG. 2;

FIG. 5 is an explanatory diagram illustrating an example of vectors of stress exerted on a standing portion and an inclined portion of each wire when a sealing member according to Embodiment 1 expands;

FIG. 6 is an explanatory diagram illustrating an example of vectors of stress exerted on a standing portion and an inclined portion of each wire in a comparative example;

FIG. 7 is a flowchart of a method of manufacturing a light-emitting apparatus according to Embodiment 1;

FIG. 8A is a cross-sectional view illustrating one step in a method of manufacturing light-emitting apparatus 10 according to Embodiment 1;

FIG. 8B is a cross-sectional view illustrating one step in a method of manufacturing light-emitting apparatus 10 according to Embodiment 1;

FIG. 8C is a cross-sectional view illustrating one step in a method of manufacturing light-emitting apparatus 10 according to Embodiment 1;

FIG. 8D is a cross-sectional view illustrating one step in a method of manufacturing light-emitting apparatus 10 according to Embodiment 1;

FIG. 9 is a plan view illustrating each light-emitting element line of a light-emitting apparatus in Variation 1 according to Embodiment 1;

FIG. 10 is a side view of a wire in Variation 2 according to Embodiment 1;

FIG. 11 is a side view of a wire and targets to be connected in Variation 3 according to Embodiment 1;

FIG. 12 is a cross-sectional view of an illumination apparatus according to Embodiment 2; and

FIG. 13 is a perspective view of external appearances of an illumination apparatus and peripheral members thereof according to Embodiment 2.

### DETAILED DESCRIPTION OF THE EMBODIMENTS

Hereinafter a light-emitting apparatus, etc., according to embodiments are described with reference to the Drawings. Note that each of the embodiments described below shows a general or specific example. The numerical values, shapes, materials, structural elements, the arrangement and connection of the structural elements, steps, the processing order of the steps, etc., shown in the following embodiments are mere examples, and therefore do not limit the present disclosure. As such, among the structural elements in the following embodiments, those not recited in any one of the independent claims which indicate the broadest inventive concepts are described as arbitrary structural elements.

Furthermore, the respective figures are schematic illustrations and are not necessarily precise illustrations. Additionally, in the figures, substantially identical elements are assigned the same reference signs, and there are cases where overlapping descriptions are omitted or simplified.

### Embodiment 1

### Configuration of Light-Emitting Apparatus

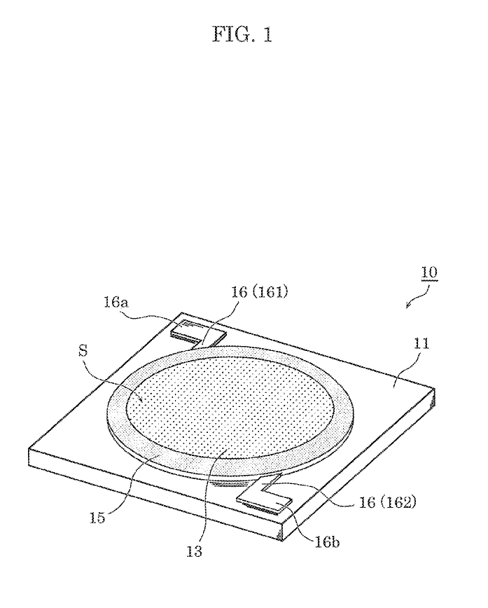

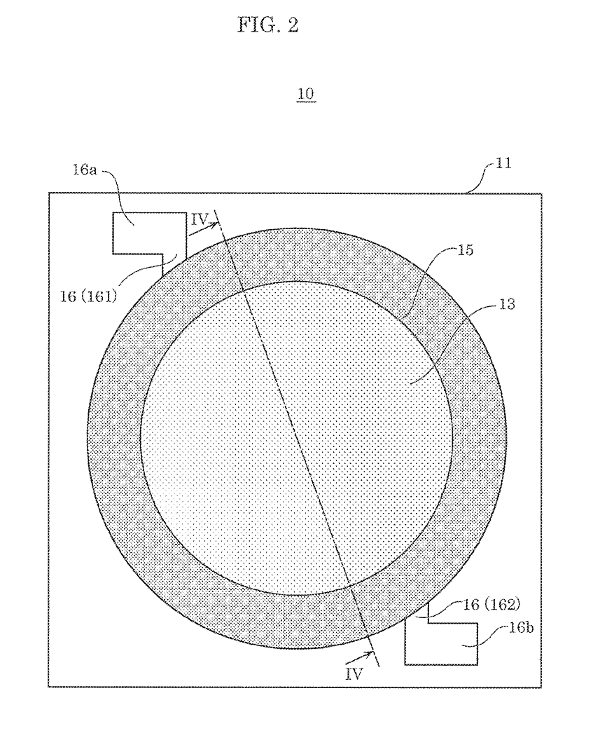

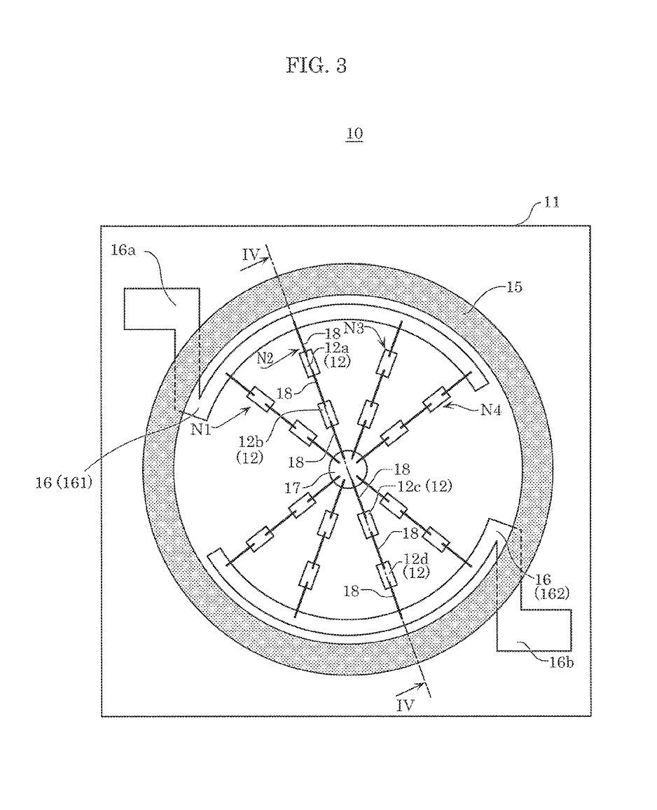

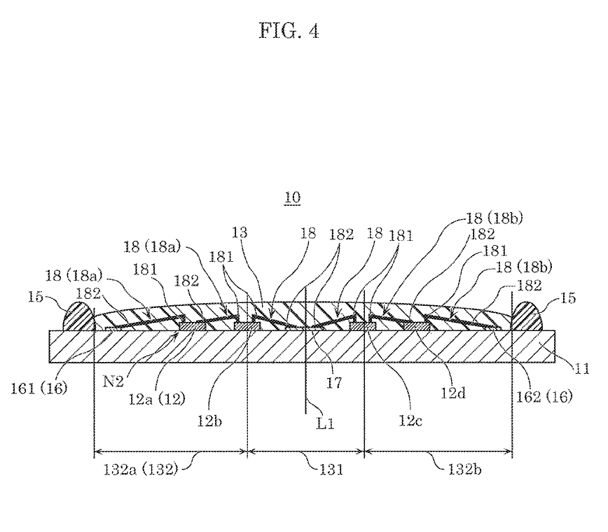

First, the configuration of a light-emitting apparatus according to Embodiment 1 will be described with reference to the Drawings. FIG. 1 is a perspective view of an external appearance of a light-emitting apparatus according to Embodiment 1. FIG. 2 is a plan view of a light-emitting apparatus according to Embodiment 1. FIG. 3 is a plan view illustrating the internal structure of a light-emitting apparatus according to Embodiment 1. FIG. 4 is a schematic cross-sectional view of a light-emitting apparatus, taken along line IV-IV in FIG. 2. Note that FIG. 3 is a plan view of the light-emitting apparatus which corresponds to that illustrated in FIG. 2 and illustrates the internal structure thereof including the arrangement of LED chips 12 and a wiring pattern with sealing member 13 removed.

Light-emitting apparatus 10 according to Embodiment 1 includes substrate 11, two or more LED chips 12, sealing member 13, and dam member (side sealing member) 15 as illustrated in FIG. 1 to FIG. 4.

Light-emitting apparatus 10 is what is called a COB (chip-on-board) LED module in which LED chips 12 are directly mounted on substrate 11.

Substrate 11 is, for example, a metal-based substrate or a ceramic substrate. Furthermore, substrate 11 may be a resin substrate that uses a resin as a base material.

An alumina substrate made of aluminum oxide (alumina), an aluminum nitride substrate made of aluminum nitride, or the like is used as the ceramic substrate. An aluminum alloy substrate, an iron alloy substrate, a copper alloy substrate, or the like, the surface of which is coated with an insulating film, for example, is used as the metal-based substrate. A glass-epoxy substrate made of glass fiber and an epoxy resin is used as the resin substrate, for example.

Note that a substrate having a high optical reflectivity (for example, an optical reflectivity of 90% or higher), for example, may be used as substrate 11. Using a substrate having a high optical reflectivity as substrate 11 allows light emitted by LED chips 12 to be reflected off the surface of substrate 11. This results in an increase in the light extraction rate of light-emitting apparatus 10. Examples of the substrate include a white ceramic substrate that uses alumina as a base material.

Alternatively, a light-transmissive substrate having high light transmittance may be used as substrate 11. Examples of the substrate include a light-transmissive ceramic substrate made of polycrystalline alumina or aluminum nitride, a clear glass substrate made of glass, a crystal substrate made of crystal, a sapphire substrate made of sapphire, or a transparent resin substrate made of a transparent resin material.

Note that substrate 11 has a rectangular shape in Embodiment 1, but may have a circular or other shape.

Substrate 11 has a wiring region in which wiring 16 and 17 is provided.

Wiring 16 is a conductive layer formed on substrate 11, for supplying electric power to LED chips 12. Wiring 16 is one pair of wires provided inside the region surrounded by dam member 15. One pair of wires 16 is formed in a circular arc shape along the inner circumference of dam member 15 in a plan view. One end of wire 161 which is one of one pair of wires 16 is located outside of dam member 15, and electrode 16a is provided to the one end. One end of wire 162 which is the other of one pair of wires 16 is located outside dam member 15, and electrode 16b is provided to the one end.

Wiring 17 is a conductive layer formed on substrate 11, for electrically relaying light-emitting element lines which are described later. Wiring 17 is formed in a center part of the region surrounded by dam member 15. The shape of wiring 17 in a plan view is a circle.

LED chip 12 is an example of a light-emitting element having a rectangular shape in a plan view. Note that the shape of LED chip 12 in a plan view is not limited to a rectangle and may be another shape such as a square and a circle.

LED chip 12 is, for example, a blue LED chip which emits blue light. Specifically, a gallium nitride LED chip formed using an InGaN-based material and having a central wavelength (a peak wavelength of the light emission spectrum) in the range from 430 nm to 480 nm is used as LED chip 12.

A plurality of light-emitting element lines including two or more LED chips 12 are provided on substrate 11. As illustrated in FIG. 3, four light-emitting element lines are radially arranged via wiring 17 on substrate 11. These four light-emitting element lines are connected in parallel with one pair of wires 16 and emit light with electric power supplied between electrode 16a and electrode 16b.

Although details are described later, LED chips 12 are connected in series in a chip-to-chip configuration mainly by wire 18 (some of LED chips 12 are connected by wiring 16). Wire 18 is a power supply wire connected to LED chips 12. Examples of a metal material of wire 18 and a metal material of wiring 16 and 17, electrode 16a, and electrode 16b mentioned above include a conductive material such as gold (Au), silver (Ag), copper (Cu), or the like.

Dam member 15 is provided on substrate 11 and serves to block sealing member 13. For example, a thermosetting resin or a thermoplastic resin having an insulating property is used as dam member 15. More specifically, a silicone resin, a phenol resin, an epoxy resin, a BT (bismaleimide-triazine) resin, PPA (polyphthalamide), or the like is used as dam member 15.

It is desirable that dam member 15 have a light-reflecting property in order to increase the light extraction rate of light-emitting apparatus 10. Thus, a resin in a white color (what is called a white resin) is used as dam member 15 in Embodiment 1. Note that in order to increase the light-reflecting property of dam member 15, TiO₂, Al₂O₃, ZrO₂, MgO, and the like particles may be contained in dam member 15.

In light-emitting apparatus 10, dam member 15 is formed in a circular annular shape so as to surround two or more LED chips 12 in a top view. Sealing member 13 is provided in the region surrounded by dam member 15. With this, it is possible to increase the light extraction rate of light-emitting apparatus 10. The outer shape of dam member 15 may be a rectangular annular shape in a plan view.

Note that dam member 15 has an effect of reducing light that leaks laterally from LED chip 12 to the outside of light-emitting apparatus 10. Since LED chip 12 emits light mainly upward (toward sealing member 13), a large amount of components of yellow light emitted from a yellow phosphor is included in an area lateral to LED chip 12, often resulting in light that does not have a desired emission color being emitted. Dam member 15 serves as a wall against such light, and is thus capable of reducing the occurrence of such light leaking to the outside of light-emitting apparatus 10.

Sealing member 13 seals a part of two or more LED chips 12, wire 18, and wiring 16. Specifically, sealing member 13 is formed of a light-transmissive resin material containing a yellow phosphor as a wavelength converting element. As the light-transmissive resin material, a methyl-based silicone resin is used, for example, but an epoxy resin, a urea resin, or the like may be used.

The yellow phosphor is one example of a phosphor (phosphor particles) and is excited by the light emitted from LED chip 12 and emits yellow fluorescent light. For example, an yttrium aluminum garnet (YAG)-based phosphor is used as the yellow phosphor.

In this configuration, the wavelength of a portion of the blue light emitted from LED chips 12 is converted by the yellow phosphor contained in sealing member 13, so that the portion is transformed into yellow light. Then, the blue light not absorbed by the yellow phosphor and the yellow light resulting from the wavelength conversion by the yellow phosphor are diffused and mixed within sealing member 13. Consequently, white light is emitted from sealing member 13.

### Electrical Connection Structure of LED Chips

As illustrated in FIG. 3, four light-emitting element lines are referred to as first light-emitting element line N1, second light-emitting element line N2, third light-emitting element line N3, and fourth light-emitting element line N4, clockwise from the left in FIG. 3. Light-emitting element lines N1 to N4 are arranged radially in such a way that the radial arrangement thereof is centered on wiring 17.

LED chips 12 in each line are referred to as first LED chip 12a, second LED chip 12b, third LED chip 12c, and fourth LED chip 12d, sequentially from one end to the other end of the line when viewed along the arrangement. Note that wiring 17 is located between second LED chip 12b and third LED chip 12c in each of light-emitting element lines N1 to N4.

All light-emitting element lines N1 to N4 have the same electrical connection structure; therefore, the electrical connection structure of second light-emitting element line N2 is described, and descriptions of the electrical connection structures of other light-emitting element lines N1, N3, and N4 are omitted. Reference signs for LED chips 12 in other light-emitting element lines N1, N3, and N4 are also omitted in FIG. 3.

As illustrated in FIG. 4, LED chips 12 included in second light-emitting element line N2, one pair of wires 16, and wiring 17 are arranged linearly, among which adjacent ones are connected individually by wires 18. In other words, LED chips 12, one pair of wires 16, and wiring 17 arranged linearly are targets to be connected by two or more wires 18.

Wire 18 is formed by wire bonding. Specifically, wire 18 includes standing portion 181 formed by first bonding in the wire bonding, and inclined portion 182 formed by second bonding in the wire bonding. Standing portion 181 and inclined portion 182 are continuously formed. Standing portion 181 is a first bonding portion which is attached to one of adjacent targets to be connected, so as to extend vertically and thus stand upward. Inclined portion 182 is a second bonding portion which is attached to the other of adjacent targets to be connected, so as to be slanted. The positional relationship between standing portion 181 and inclined portion 182 of wire 18 is determined according to where wire 18 is provided.

For example, sealing member 13 is separated between central region 131 and peripheral region 132.

Central region 131 is, in a plan view, a circular region including the center of sealing member 13. Peripheral region 132 is, in a front view, an annular region located outside of central region 131 when viewed in a plan view. Central region 131 and peripheral region 132 may either be spaced apart from each other or be adjacent to each other; the present embodiment describes an example where they are adjacent to each other. Note that although peripheral region 132 has an annular shape in a plan view as mentioned above, central region 131 separates peripheral region 132 into two parts in a view taken along second light-emitting element line N2. Among the separated parts of peripheral region 132, a region on first LED chip 12a side corresponding to one end is referred to as first peripheral region 132a, and a region on fourth LED chip 12d side corresponding to the other end is referred to as second peripheral region 132b.

First peripheral region 132a includes two wires 18 that are wire 18 connecting one wire 161 and first LED chip 12a and wire 18 connecting first LED chip 12a and second LED chip 12b. These two wires 18 are each first wire 18a which has standing portion 181 attached to the inner one of the targets to be connected and inclined portion 182 attached to the outer one of the targets to be connected.

Second peripheral region 132b includes two wires 18 that are wire 18 connecting third LED chip 12c and fourth LED chip 12d and wire 18 connecting fourth LED chip 12d and other wire 162. These two wires 18 are each second wire 18b which has standing portion 181 attached to the inner one of the targets to be connected and inclined portion 182 attached to the outer one of the targets to be connected.

It is sufficient that the region of sealing member 13 corresponding to one end includes at least wire 18 disposed at one end of one line of two or more wires 18. Likewise, it is sufficient that the region of sealing member 13 corresponding to the other end includes at least wire 18 disposed at the other end of the one line of two or more wires 18.

The positional relationship between standing portion 181 and inclined portion 182 of wire 18 included in peripheral region 132 is as just described, that is, standing portion 181 is attached to one of the targets to be connected by wire 18 that is the inner one of the targets in sealing member 13, and inclined portion 182 is attached to the other of the targets to be connected by wire 18 that is the outer one of the targets in sealing member 13.

Central region 131 includes two wires 18 that are wire 18 connecting second LED chip 12b and wire 17 and wire 18 connecting wire 17 and third LED chip 12c. Each of these two wires 18 has standing portion 181 attached to the inner one of the targets to be connected and inclined portion 182 attached to the outer one of the targets to be connected.

This means that standing portion 181 and inclined portion 182 of each of two or more wires 18 are positioned in such a way that wires 18 have line symmetry with respect to the center of a line of wires 18. In FIG. 4, the vertical line passing through the center of the line of wires 18 is denoted as center line L1 of line symmetry. Center line L1 preferably passes through the vicinity of the center of sealing member 13 when viewed in a plan view.

A heat change that occurs due to LED chip 12 being turned on and off causes thermal deformation of sealing member 13. When sealing member 13 expands thermally, the entirety thereof expands like a pancake. Specifically, sealing member 13 swells radially from the center thereof in a plan view. Also in the side cross-sectional view illustrated in FIG. 4, sealing member 13 swells radially from the center thereof. In other words, sealing member 13 expands three-dimensionally. When sealing member 13 contracts, sealing member 13 contracts in a direction opposite to the direction in which sealing member 13 expands. Stress is exerted on each wire 18 when sealing member 13 expands and contracts due to heat as just described.

The inventor of the present invention calculated stress exerted on standing portion 181 and inclined portion 182 of each wire 18 in simulation.

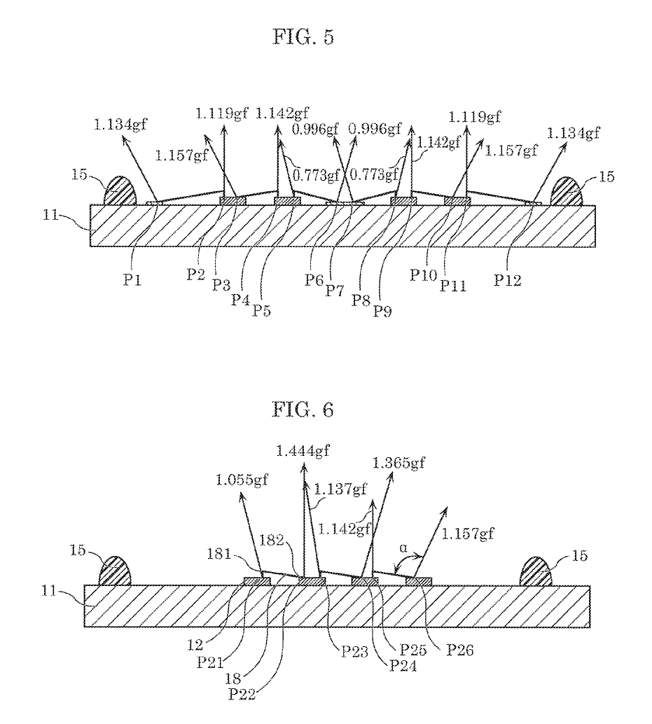

FIG. 5 is an explanatory diagram illustrating an example of vectors of stress exerted on standing portion 181 and inclined portion 182 of each wire 18 when sealing member 13 according to Embodiment 1 expands. In FIG. 5, illustration of sealing member 13 is omitted. Standing portions 181 and inclined portions 182 of wires 18 are referred to as first connection point P1 to twelfth connection point P12, sequentially from one end of the line (sequentially from the left in FIG. 5). As illustrated in FIG. 5, stress exerted at first connection point P1 and stress exerted at twelfth connection point P12 have the same value, that is, 1.134 gf, stress exerted at second connection point P2 and stress exerted at eleventh connection point P11 have the same value, that is, 1.119 gf, stress exerted at third connection point P3 and stress exerted at tenth connection point P10 have the same value, that is, 1.157 gf, stress exerted at fourth connection point P4 and stress exerted at ninth connection point P9 have the same value, that is, 1.142 gf, stress exerted at fifth connection point P5 and stress exerted at eighth connection point P8 have the same value, that is, 0.773 gf; and stress exerted at sixth connection point PG and stress exerted at seventh connection point P7 have the same value, that is, 0.996 gf.

Thus, two or more wires 18 are arranged so as to have line symmetry with respect to center line L1, resulting in equivalent stress being exerted at corresponding connection points.

The following describes, as a comparative example, stress exerted on standing portion 181 and inclined portion 182 of each wire 18 when each wire 18 is positioned in the same direction.

FIG. 6 is an explanatory diagram illustrating an example of vectors of stress exerted on standing portion 181 and inclined portion 182 of each wire 18 in the comparative example.

The comparative example shows a case where four LED chips 12 are arranged in one line. Each wire 18 connecting LED chips 12 is positioned in such a way that standing portion 181 and inclined portion 182 thereof are arranged sequentially in the stated order from one end of the line of LED chips 12 (sequentially from the left in FIG. 6). In the comparative example, the center of the line of two or more wires 18 is positioned in the vicinity of the center of sealing member 13 in a plan view. Under the same condition as that in the above embodiment except that just described, stress exerted on-standing portion 181 and inclined portion 182 of each wire 18 in the comparative example was calculated in simulation.

In the comparative example, standing portions 181 and inclined portions 182 of wires 18 are referred to as first connection point P21 to sixth connection point P26, sequentially from one end of the line (sequentially from the left in FIG. 6). As illustrated in FIG. 6, stress exerted at first connection point P21 is 1.055 gf, stress exerted at second connection point P22 is 1.444 gf, stress exerted at third connection point P23 is 1.137 gf, stress exerted at fourth connection point P24 is 1.142 gf, stress exerted at fifth connection point P25 is 1.365 gf and stress exerted at sixth connection point P26 is 1.157 gf.

In such a case as the comparative example where wires 18 are positioned so as to match the directionalities of all wires 18 each other, the maximum value of stress exerted at connection points P21 to P26 is 1.444 gf. In the present embodiment, the maximum value of stress exerted at connection points P1 to P12 is 1.157 gf which is about 20% lower than that in the comparative example.

Furthermore, in the comparative example, the point at which stress having the maximum value is exerted is second connection point P22, which is in the region corresponding to one end of the entire line. In this region, the extent of swelling of sealing member 13 is large, which makes the stress thereon large as well. Moreover, inclined portion 182 of wire 18 is disposed at second connection point P22. Inclined portion 182 formed by the second bonding is less likely to be disconnected because of resistance to stress exerted thereon when angle α between the direction in which inclined portion 182 extends and the vector of the stress is approximately 90 degrees or more, but is more likely to be disconnected when angle α is less than 90 degrees. Therefore, since angle α is less than 90 degrees at second connection point P22, disconnection at the portion is more likely when large stress is exerted thereon.

In the present embodiment, angle α is 90 degrees or more at every inclined portions 182 as is clear from FIG. 5. Thus, the occurrence of disconnection at inclined portion 182 due to sealing member 13 expanding can be reduced.

### Method of Manufacturing Light-Emitting Apparatus

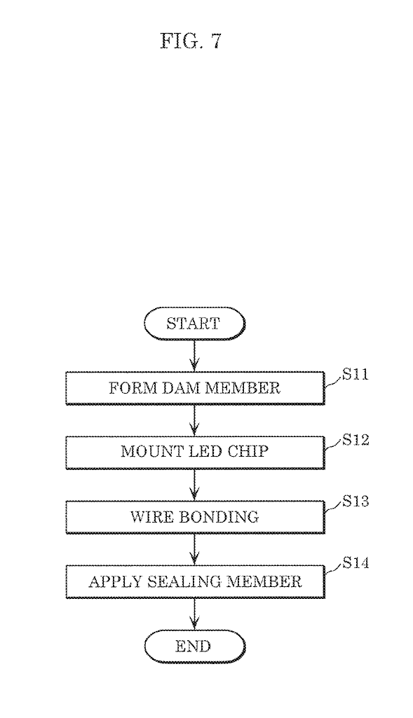

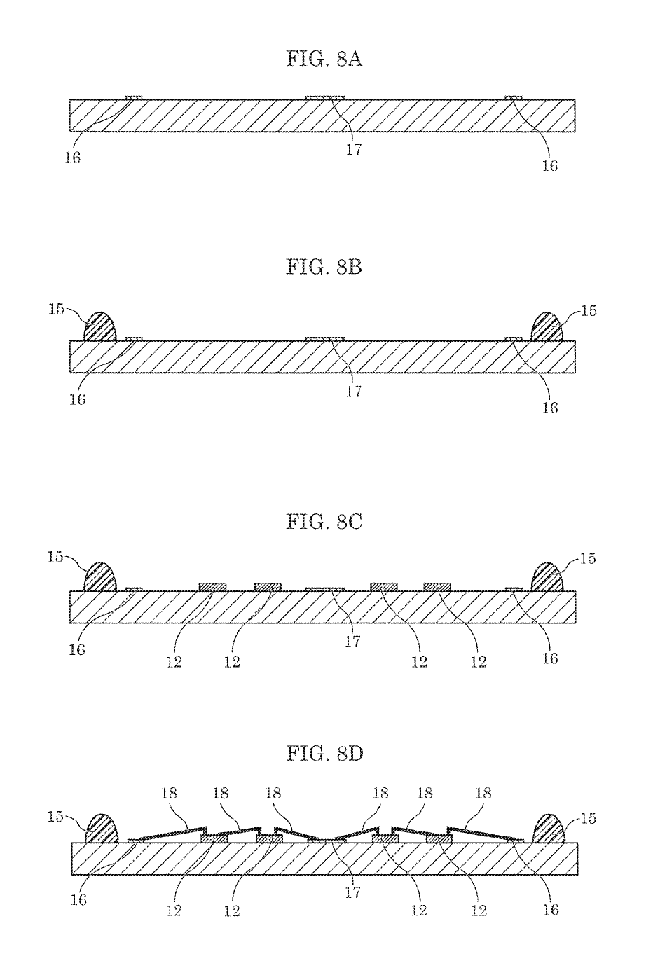

Next, a method of manufacturing light-emitting apparatus 10 is described. FIG. 7 is a flowchart of a method of manufacturing light-emitting apparatus 10 according to Embodiment 1. FIG. 8A to FIG. 8D are cross-sectional views each illustrating one step in a method of manufacturing light-emitting apparatus 10 according to Embodiment 1. Note that FIG. 8A to FIG. 8D are views corresponding to FIG. 4.

First, on substrate 11 on which wiring 16 and 17 has been formed in advance as illustrated in FIG. 8A, dam member 15 is formed as illustrated in FIG. 8B (S11). Dam member 15 is formed in a circular annular shape that is continuous to partially cover wiring 16. A dispenser that releases a white resin is used to form dam member 15.

Next, two or more LED chips 12 are mounted on substrate 11 as illustrated in FIG. 8C (S12). A die-attach material or the like is used to mount LED chips 12 by die bonding.

Next, as illustrated in FIG. 8D, wires 18 which connect LED chips 12 and wiring 16 and 17 are provided by wire bonding. At this time, standing portion 181 of each wire 18 is formed by the first bonding in the wire bonding, and inclined portion 182 of each wire 18 is formed by the second bonding in the wire bonding.

With this, two or more LED chips 12 are electrically connected to each other by wires 18 and wiring 16 and 17.

Sealing member 13 fills (is applied to) the region surrounded by dam member 15, as illustrated in FIG. 4 (S14). Specifically, a light-transmissive resin material containing yellow phosphor particles is injected into the region. When the injection of the light-transmissive resin material is completed, the light-transmissive resin material is subject to heating, light irradiation, or the like so as to be cured, forming sealing member 13.

### Advantageous Effects, Etc.

As described above, wire 18 included in a region of sealing member 13 (first peripheral region 132a) corresponding to one of ends of a line of targets to be connected (LED chips 12 and wiring 16 and 17) has standing portion 181 attached to the inner one of the targets to be connected and inclined portion 182 attached to the outer one of the targets to be connected. Furthermore, wire 18 included in a region of sealing member 13 (second peripheral region 132b) corresponding to the other of the ends of the line of the targets to be connected has standing portion 181 attached to the inner one of the targets to be connected and inclined portion 182 attached to the outer one of the targets to be connected.

Thus, inclined regions 182 of wires 18 included in the region corresponding to one end and in the region corresponding to the other end both slope outward and downward. Specifically, angle α between the direction in which inclined portion 182 extends and the vector of stress exerted thereon is approximately 90 degrees or more, meaning that disconnection is not likely. Thus, disconnection of wire 18 due to thermal deformation of sealing member 13 can be reduced, increasing the reliability.

Furthermore, since a plurality of targets to be connected which form one line include two or more LED chips 12 and wiring 16 and 17, the occurrence of wire 18 that connects LED chips 12 being disconnected and the occurrence of wire 18 that connects wiring 16 and 17 being disconnected can be reduced.

Furthermore, standing portion 181 and inclined portion 182 of each wire 18 are positioned in such a way that two or more wires 18 that form one line have line symmetry with respect to the center of the line of two or more wires 18 (center line L1). With this, variations in stress that is exerted on all wires 18 can be reduced. Therefore, the occurrence of excessive stress being exerted on part of wires 18 can be reduced, and thus the occurrence of disconnection can be further reduced.

A distinguishing feature disclosed herein can also be applied to a light-emitting apparatus in which a sealing member is linearly provided, such as a line module. In light-emitting apparatus 10 according to the present embodiment, however, sealing member 13 is two-dimensionally provided unlike in the line module, and therefore the size of sealing member 13 is greater than that in the line module. The amount of thermal deformation of sealing member 13 is greater than that in the line module. This means that light-emitting apparatus 10 having what is called a dam structure, in which the region surrounded by dam member 15 is filled with sealing member 13 as in the present embodiment, is capable of producing a more pronounced effect of reducing the occurrence of disconnection.

Furthermore, since a plurality of lines of the targets to be connected and two or more wires 18 intersect one another and are radially arranged, variations in the stress exerted horizontally thereon from sealing member 13 formed in a circular shape in a plan view can be reduced. Therefore, the occurrence of excessive stress being exerted horizontally on part of wires 18 can also be reduced, and thus the occurrence of disconnection can be further reduced.

### Variation 1

The following describes Variation 1 according to the present embodiment. In the following descriptions, elements that are identical to those in the above embodiment are assigned the same reference signs, and there are cases where descriptions thereof are omitted.

Above Embodiment 1 has described an example where the light-emitting element lines are arranged radially in a plan view. The present variation describes an example where the light-emitting element lines are arranged in parallel along the same direction.

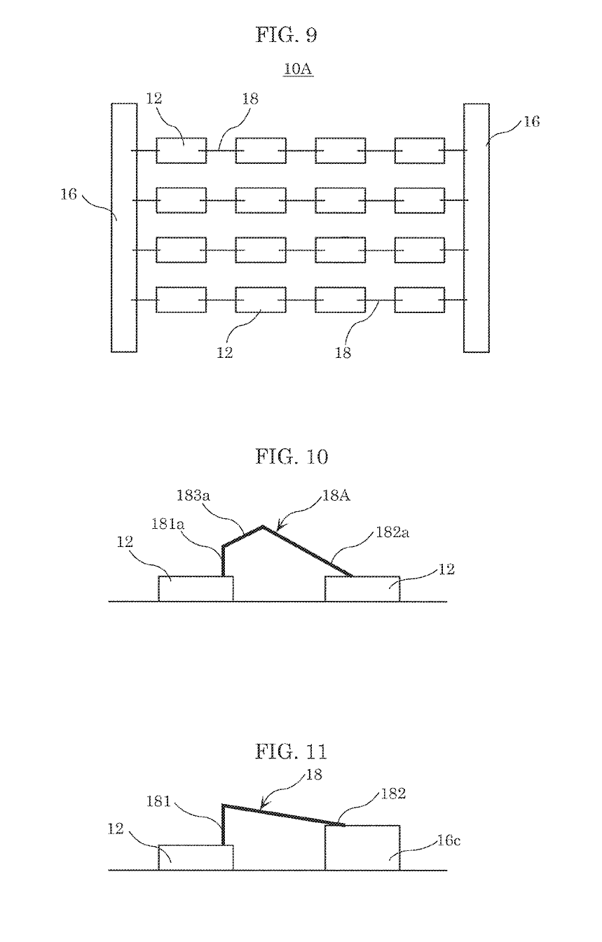

FIG. 9 is a plan view illustrating each light-emitting element line of light-emitting apparatus 10A in Variation 1 according to Embodiment 1.

As illustrated in FIG. 9, light-emitting apparatus 10A includes four light-emitting element lines in each of which four LED chips 12 are arranged linearly, and the directions in each of which four LED chips 12 are arranged are in parallel.

These four light-emitting element lines are disposed in the region surrounded by dam member 15 on substrate 11 and sealed with sealing member 13. LED chips 12 at both ends of each light-emitting element line are connected to wiring 16 by wires 18. LED chips 12 adjacent to each other along the line are also connected by wire 18.

In each light-emitting element line, wire 18 at one end or wire 18 inwardly adjacent to wire 18 at one end is included in the region of the sealing member corresponding to one end. At least one of wires 18 included in the region corresponding to one end is a first wire.

In each light-emitting element line, wire 18 at the other end or wire 18 inwardly adjacent to wire 18 at the other end is included in the region of the sealing member corresponding to the other end. At least one of wires 18 included in the region corresponding to the other end is a second wire.

With this, the occurrence of wire 18 being disconnected can be reduced in the light-emitting element lines arranged as illustrated in FIG. 9 as well.

Note that the arrangement of the light-emitting element lines is not limited to those in above Embodiment 1 and Variation 1 and may be a different arrangement. Furthermore, the number of LED chips 12 per line may be other than four as long as it is more than one.

Furthermore, in the above embodiment, all wires 18 included in the region of sealing member 13 (first peripheral region 132a) corresponding to one end and in the region of sealing member 13 (second peripheral region 132b) corresponding to the other end are provided in such a way that respective standing portions 181 are located inward and respective inclined portions 182 are located outward. However, it is sufficient that at least one of such wires 18 is provided in each of the region corresponding to one end and the region corresponding to the other end to reduce the occurrence of targeted wire 18 being disconnected. This means that any arrangement of wires 18 is allowed if this condition is satisfied. Specifically, two or more wires 18 that form one line are not required to have line symmetry with respect to center line L1.

### Variation 2

The following describes Variation 2 according to the present embodiment.

Above Embodiment 1 has described a case where standing portion 181 and inclined portion 182 of wire 18 are continuous. Variation 2 describes a case where standing portion 181 and inclined portion 182 are non-continuous.

FIG. 10 is a side view of a wire in Variation 2 according to Embodiment 1.

As illustrated in FIG. 10, wire 18A includes: standing portion 181a attached to LED chip 12 that is one of the targets to be connected; inclined portion 182a attached to LED chip 12 that is the other of the targets to be connected; and joining portion 183a which joins standing portion 181a and inclined portion 182a together. Adjustment of the length of joining portion 183a allows an inclination angle of inclined portion 182a to be adjusted, allowing angle α to be controlled.

Note that in wire 18 according to Embodiment 1, it is possible to adjust the inclination angle of inclined portion 182 as well by adjusting the length of standing portion 181, but the overall length of wire 18 needs to be increased. In this regard, in wire 18A according to Variation 2, it is possible to adjust the inclination angle while an increase in the overall length of wire 18A is smaller than that of wire 18 according to Embodiment 1.

### Variation 3

The following describes Variation 3 according to the present embodiment.

Above Embodiment 1 has described an example where the targets to be connected by wires 18 are LED chips 12 and wiring 16 and 17. Variation 3 describes an example where the targets to be connected include elements other than those described above.

FIG. 11 is a side view of wire 18 and targets to be connected in Variation 3 according to Embodiment 1

In FIG. 11, LED chip 12 and circuit component 16c are illustrated as the targets to be connected by wire 18. Circuit component 16c is thicker than wiring 16 and 17 and LED chips 12 described above. Standing portion 181 of wire 18 is attached to LED chip 12, and inclined portion 182 is attached to circuit component 16c. Even when a connection position of inclined portion 182 is higher than a connection position of standing portion 181 as just described, the occurrence of wire 18 being disconnected can be reduced.

### Embodiment 2

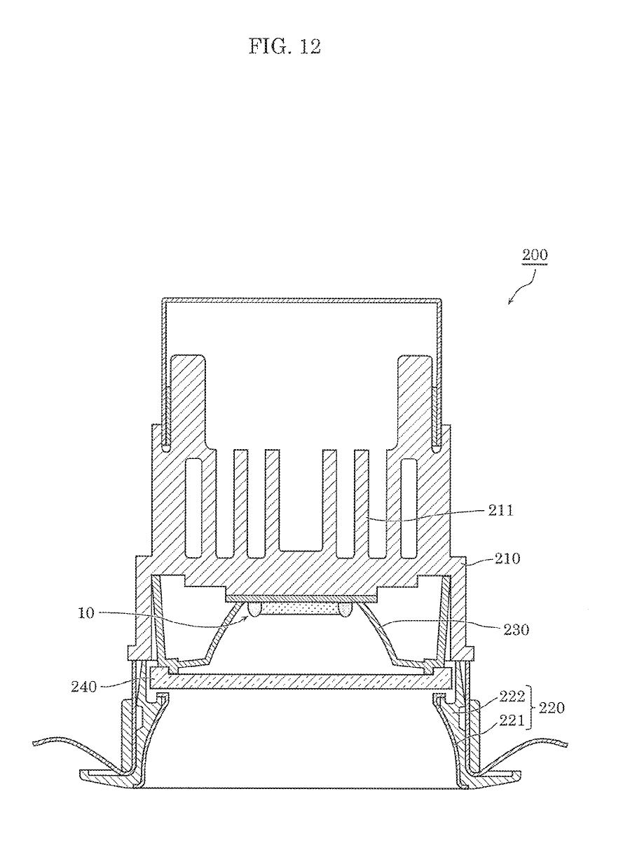

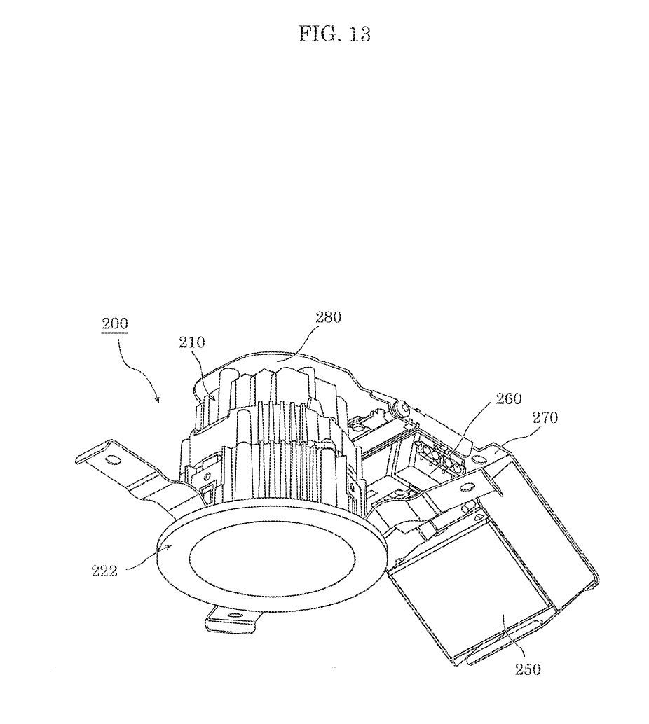

Next, illumination apparatus 200 according to Embodiment 2 is described with reference to FIG. 12 and FIG. 13. FIG. 12 is a cross-sectional view of illumination apparatus 200 according to Embodiment 2. FIG. 13 is a perspective view of external appearances of illumination apparatus 200 and peripheral members thereof according to Embodiment 2.

As illustrated in FIG. 12 and FIG. 13, illumination apparatus 200 according to Embodiment 2 is a sunken illumination apparatus, such as a recessed light, that emits light downward (toward the floor or a wall, for example) by being installed, for example, in the ceiling of a house.

Illumination apparatus 200 includes light-emitting apparatus 10. Illumination apparatus 200 further includes an apparatus body in the shape of a substantial bottomed tube formed by joining pedestal 210 and frame 220, and reflection plate 230 and light-transmissive panel 240 disposed on this apparatus body.

Pedestal 210 is an attachment base to which light-emitting apparatus is attached, and also serves as a heat sink for dissipating heat generated by light-emitting apparatus 10. Pedestal 210 is formed into a substantially columnar shape using a metal material and is, in Embodiment 2, made of die-cast aluminum.

Two or more heat-dissipating fins 211 are provided at predetermined intervals along one direction on the top portion (ceiling-side portion) of pedestal 210 so as to protrude upward. With this, heat generated by light-emitting apparatus 10 can be efficiently dissipated.

Frame 220 includes: cone portion 221 including a reflective surface on an inner surface and having a substantially circular tube shape; and frame body 222 to which cone portion 221 is attached. Cone portion 221 is formed using a metal material and can, for example, be formed of an aluminum alloy or the like by metal spinning or pressing. Frame body 222 is formed of a hard resin material or a metal material. Frame 220 is fixed by frame body 222 being attached to pedestal 210.

Reflection plate 230 is a circular-annular-frame-shaped (funnel-shaped) reflection member having an inner surface reflection function. For example, reflection plate 230 can be formed using a metal material such as aluminum. Note that reflection plate 230 may be formed using a hard white resin material instead of a metal material.

Light-transmissive panel 240 is a light-transmissive member having light-diffusing properties and light-transmitting properties. Light-transmissive panel 240 is a flat plate disposed between reflection plate 230 and frame 220, and is attached to reflection plate 230. For example, light-transmissive panel 240 can be formed into a disc shape using a transparent resin material such as acrylic or polycarbonate.

Note that illumination apparatus 200 is not required to include light-transmissive panel 240. Without light-transmissive panel 240, illumination apparatus 200 allows an improvement in the luminous flux of light that is output therefrom.

Furthermore, as illustrated in FIG. 13, lighting apparatus 250 which supplies lighting power to light-emitting apparatus 10, and terminal base 260 which relays AC power from a commercial power supply to lighting apparatus 250 are connected to illumination apparatus 200.

Lighting apparatus 250 and terminal base 260 are fixed to attachment plate 270 provided separately from the apparatus body. Attachment plate 270 is formed by folding a rectangular plate member made of a metal material, and has one longitudinal end the bottom surface of which lighting apparatus 250 is fixed to and the other longitudinal end the bottom surface of which terminal base 260 is fixed to. Attachment plate 270 is connected together with top plate 280 which is fixed to a top portion of pedestal 210 of the apparatus body.

In illumination apparatus 200 as a result of including light-emitting apparatus 10, the occurrence of wire 18 being disconnected can be reduced. Thus, it can be said that illumination apparatus 200 is highly reliable.

Although the illumination apparatus is exemplified as a recessed light in Embodiment 2, the illumination apparatus according to the present disclosure may be implemented as a spotlight or a different illumination apparatus.

### Other Embodiments

Although light-emitting apparatus 10, the method of manufacturing the same, and illumination apparatus 200 according to the embodiments have been described above, the present disclosure is not limited to the above-described embodiments.

Furthermore, although COB light-emitting apparatus 10 has been described in the above embodiments, the present disclosure is applicable to a SMD (surface mount device) light-emitting apparatus as well.

Furthermore, in the above embodiments, light-emitting apparatus 10 outputs white light using a combination of LED chip 12 that emits blue light with the yellow phosphor, but the configuration for outputting white light is not limited to that described above.

For example, a phosphor-containing resin that contains a red phosphor and a green phosphor may be combined with LED chip 12. Alternatively, an ultraviolet LED chip that outputs ultraviolet light having a wavelength shorter than that of light output from LED chip 12 may be combined with a blue phosphor, a red phosphor, and a green phosphor that output blue light, red light, and green light, respectively, as a result of being excited mainly by ultraviolet light.

Furthermore, the light-emitting element to be used in light-emitting apparatus 10 is exemplified as LED chip 12 in the above embodiments. However, a semiconductor light-emitting element, such as a semiconductor laser, or another type of solid-state light-emitting element, such as an electroluminescent (EL) element including an organic or inorganic EL material, may be used as the light-emitting element.

Furthermore, light-emitting elements of two or more types different in light-emission color may be used in light-emitting apparatus 10. For example, light-emitting apparatus 10 may include an LED chip that emits red light in addition to LED chip 12 for the purpose of increasing color rendering properties.

Furthermore, the above embodiments have described an example of light-emitting apparatus 10 in which two or more LED chips 12 are two-dimensionally arranged in the region surrounded by dam member 15 and sealed with sealing member 13. A distinguishing feature disclosed herein can also be applied to a light-emitting apparatus that is what is called a line module in which a plurality of LED chips are linearly arranged and sealed with a sealing member.

While the foregoing has described one or more embodiments and/or other examples, it is understood that various modifications may be made therein and that the subject matter disclosed herein may be implemented in various forms and examples, and that they may be applied in numerous applications, only some of which have been described herein. It is intended by the following claims to claim any and all modifications and variations that fall within the true scope of the present teachings.

What is claimed is:

1. A light-emitting apparatus comprising:
a substrate;
a plurality of targets to be connected, mounted on the substrate and arranged linearly;
a plurality of wires that connect the plurality of targets in series by individually connecting adjacent ones of the plurality of targets to each other; and
a sealing member provided on the substrate and sealing the plurality of targets and the plurality of wires,
wherein the plurality of wires includes at least a first wire and a second wire,
the first wire is included in a region of the sealing member corresponding to one of ends of a line of the plurality of targets,
the second wire is included in a region of the sealing member corresponding to the other of the ends,
each of the first wire and the second wire has a standing portion attached to one of targets, and an inclined portion attached to an other of the targets, and
the one of the targets is located at an inner position in the sealing member than the other of the targets in a plan view.

2. The light-emitting apparatus according to claim 1,
wherein the plurality of targets include a plurality of light-emitting elements and a conductive layer provided on the substrate.

3. The light-emitting apparatus according to claim 1,
wherein the first wire and the second wire are positioned to give the plurality of wires line symmetry with respect to a vertical line passing through a center of a line of the plurality of wires.

4. The light-emitting apparatus according to claim 1, further comprising
a dam member provided on the substrate and surrounding the plurality of targets and the plurality of wires,
wherein in a region surrounded by the dam member, the plurality of targets and the plurality of wires are provided in a plurality of lines, and
the sealing member fills the region surrounded by the dam member.

5. The light-emitting apparatus according to claim 4,
wherein the plurality of lines of the plurality of targets and the plurality of wires intersect one another and are radially arranged.

6. An illumination apparatus comprising:
the light-emitting apparatus according to claim 1.

7. A method of manufacturing a light-emitting apparatus according to claim 1, comprising, when connecting the plurality of targets to each other by forming the plurality of wires by wire bonding;
forming the standing portion of each of the first wire and the second wire by first bonding in the wire bonding; and
forming the inclined portion of each of the first wire and the second wire by second bonding in the wire bonding.
